(19) United States
(12) Patent Application Publication
(10) Pub. No.: US 2021/0118985 A1
(43) Pub. Date: Apr. 22, 2021

(54) CIRCUITS EMPLOYING ON-DIFFUSION (OD) EDGE (ODE) DUMMY GATE STRUCTURES IN CELL CIRCUIT WITH INCREASED GATE DIELECTRIC THICKNESS TO REDUCE LEAKAGE CURRENT

(71) Applicant: QUALCOMM Incorporated, San Diego, CA (US)

(72) Inventors: Xia Li, San Diego, CA (US); Haining Yang, San Diego, CA (US); Bin Yang, San Diego, CA (US)

(21) Appl. No.: 17/022,338

(22) Filed: Sep. 16, 2020

Related U.S. Application Data
(60) Provisional application No. 62/923,385, filed on Oct. 18, 2019.

(51) Int. Cl. H01L 29/06; H01L 27/088; H01L 21/8234

(52) U.S. Cl. CPC H01L 29/0607; H01L 21/823431; H01L 21/823437; H01L 27/0886

(57) ABSTRACT

Circuits employing on-diffusion (OD) edge (ODE) dummy gate structures in cell circuit with increased gate dielectric thickness to reduce leakage current are disclosed. A gate dielectric structure may be formed between a work function metal structure of an ODE dummy gate structure and an active semiconductor structure in a cell circuit, and is provided to be thicker than a gate dielectric structure formed between a work function metal structure and an active gate(s) in the cell circuit. Providing a gate dielectric structure of increased thickness can reduce damage to the gate dielectric structure providing isolation between the ODE dummy gate structure and the active semiconductor structure. Providing a gate dielectric structure of increased thickness can also reduce the gap area adjacent to the ends of the active semiconductor structures and thus reduce the volume of work function metal structure formed in the gaps to further reduce leakage current.

### PRIORITY

The present application claims priority under 35 U.S.C. § 119(e) to U.S. Provisional Patent Application Ser. No. 62/923,385, filed on Oct. 18, 2019 and entitled “CIRCUITS EMPLOYING ON-DIFFUSION (OD) EDGE (ODE) DUMMY GATE STRUCTURES IN CELL CIRCUIT WITH THICKER GATE DIELECTRIC TO REDUCE LEAKAGE CURRENT,” the contents of which is incorporated herein by reference in its entirety.

### BACKGROUND

### I. Field of the Disclosure

The field of the disclosure relates to transistors, such as Fin Field-Effect Transistors (FETs) (FinFETs) in integrated circuits (ICs), and more particularly to use of on-diffusion (OD) edge (ODE) dummy gate structures (e.g., poly (metal gate) OD edge (PODE) structures) on cell circuit edges to protect ends of semiconductor fins of FETs.

### II. BACKGROUND

Transistors are essential components in modern electronic devices. Large numbers of transistors are employed in integrated circuits (ICs) in many modern electronic devices. For example, components such as central processing units (CPUs), digital signal processors (DSPs), and memory systems each employ a large quantity of transistors for logic circuits and memory devices. Transistors can be used to form complementary metal oxide semiconductor (CMOS) circuits in ICs.

To address the need to scale down channel lengths in transistors while avoiding or mitigating short channel effects (SCEs), transistor designs alternative to planar transistors have been developed. One such alternative transistor design includes a Fin Field-Effect Transistor (FET) (FinFET) that provides a conducting channel via a “Fin” formed from a substrate. Material is wrapped around the Fin to form a gate of the FinFET. A FinFET includes a Fin of semiconductor material to form a semiconductor structure. The Fin is surrounded by a “wrap-around” gate. The wrap-around structure of the gate provides better electrostatic control over the fin channel, and thus helps reduce leakage current and overcoming other SCEs. A gate-all-around (GAA) FET is another alternative transistor that has been developed to avoid or mitigate SCEs. A GAA FET includes a nanostructure of semiconductor material (e.g., a nanowire, nanoslab, nanosheet) to form a semiconductor structure. The nanostructure is surrounded by a gate. FinFETs and GAA FETs can be used to form CMOS circuits in ICs.

### SUMMARY OF THE DISCLOSURE

Aspects disclosed herein include circuits employing on-diffusion (OD) edge (ODE) dummy gate structures in cell circuit with increased gate dielectric thickness to reduce leakage current. An integrated circuit (“circuit”) is provided that includes at least one active semiconductor region (also referred to as “diffusion region”) formed in a substrate. For example, the circuit can include a P-type active semiconductor region(s) and an N-type active semiconductor region(s) (e.g. diffusion regions) formed in a substrate to form complementary metal oxide semiconductor (CMOS) circuits. A diffusion barrier can be formed on an edge of the circuit to provide isolation between a cell circuit and an adjacent cell circuit formed on the substrate. One or more active semiconductor structures (e.g., a fin) of the cell circuit are formed in the active semiconductor regions to form semiconductor channels for field effect transistors (FETs). A plurality of gates are formed over the active semiconductor structures to provide gates for FETs and/or routing in a cell circuit. One or more of the gates are dummy gates that are ODE dummy gate structures formed over ends of the active semiconductor structure(s) at the edge of the cell circuit to provide an additional dummy gate pattern to protect an active gate during the fabrication of the circuit. Because the ODE dummy gate structures are disposed over ends of the active semiconductor structure, gaps may be present that are adjacent to the ends of the active semiconductor structures, allowing for an increased volume of work function metal structures to be formed for the ODE dummy gate structures and thus leading to leakage current. Opening and etching the ODE dummy gate structure area of the cell circuit when forming dummy gates in the cell circuit can cause the gate dielectric structure disposed on the active semiconductor structure to be damaged, thus reducing isolation between an ODE dummy gate structure and the active semiconductor structure. A reduced isolation between the ODE dummy gate structure and the active semiconductor structure can increase current leakage.

In this regard, in exemplary aspects disclosed herein, a gate dielectric structure formed between a work function metal structure of the ODE dummy gate structures and an active semiconductor structure in a cell circuit is provided to have an increased thickness. The gate dielectric structure is formed to be thicker (e.g., in a height direction) than a gate dielectric structure formed between a work function metal structure and an active gate(s) in the cell circuit. The ODE dummy gate structure may be a poly (metal gate) ODE (PODE) dummy gate structure as an example. Providing a gate dielectric structure of increased thickness between an ODE dummy gate structure and an active semiconductor structure can offset damage to the gate dielectric structure that provides isolation between the ODE dummy gate structure and the active semiconductor structure. Providing a gate dielectric structure of increased thickness between an ODE dummy gate structure and the active semiconductor structure can also reduce the gap area adjacent to ends of the active semiconductor structures and thus reduce the volume of work function metal structure formed in the gaps to further reduce leakage current.

In this regard, in one exemplary aspect, a circuit is provided. The circuit comprises an active semiconductor structure comprising a first surface. The circuit also comprises at least one active gate each disposed adjacent to the active semiconductor structure and each comprising a gate dielectric structure having a first thickness above the first surface of the active semiconductor structure. The circuit also comprises an ODE dummy gate structure comprising a second gate dielectric structure having a second thickness above an end of the active semiconductor structure greater than the first thickness.

In another exemplary aspect, a method of fabricating a cell circuit is provided. The method comprises forming an active semiconductor region in a substrate. The method also comprises forming an active semiconductor structure comprising a first surface above the substrate in the active semiconductor region. The method also comprises forming a plurality of dummy gates above the active semiconductor structure, the plurality of dummy gates comprising at least one active gate region and an ODE dummy gate structure region disposed above an end of the active semiconductor structure. The method also comprises replacing the plurality of dummy gates with a respective plurality of metal gates, comprising disposing a gate dielectric structure in the at least one active gate region and the ODE dummy gate structure region on the first surface of the active semiconductor structure, the gate dielectric structure having a first thickness above the first surface of the active semiconductor structure, and disposing a second gate dielectric structure in the ODE dummy gate structure region on the gate dielectric structure above the end of the active semiconductor structure such that the gate dielectric structure and the second gate dielectric structure form an ODE dummy gate dielectric structure having a second thickness greater than the first thickness.

### BRIEF DESCRIPTION OF THE FIGURES

FIG. 1 is a perspective view of an exemplary Fin Field-Effect Transistor (FET) (FinFET);

FIG. 2 is a top view of a cell circuit that includes P-type and N-type active semiconductor regions isolated by a double diffusion break (DDB) with gate and fin structures for forming P-type and N-type FinFETs;

FIG. 3A is a side view of an active semiconductor region in the cell circuit in FIG. 2 that illustrates an active gate and poly (metal gate) on-diffusion (OD) edge (ODE) dummy gate structures on the cell circuit edges to protect an active gate and illustrating gaps formed by the poly (metal gate) ODE (PODE) dummy gate structures only being disposed over approximately half the ends of the fins;

FIG. 3B is another side view of an active semiconductor region in the cell circuit in FIGS. 2 and 3A that illustrates more detail on an active gate and PODE dummy gate structures;

FIGS. 4A and 4B are respective top and cross-sectional side views of an exemplary circuit that includes adjacent cell circuits each having active semiconductor structures (e.g., fins), active gates, and an ODE dummy gate structure (e.g., a PODE dummy gate structure) disposed around the active semiconductor structures, wherein a gate dielectric structure formed between a work function metal structure of an ODE dummy gate structure and an active semiconductor structure is provided to be thicker than a gate dielectric structure formed between a work function metal structure and an active semiconductor structure of an active gate(s) in the cell circuit to reduce leakage current;

FIG. 4C is another cross-sectional side view of the circuit in FIG. 4B;

FIG. 5 is a top view of an exemplary circuit that includes adjacent cell circuits each having active semiconductor structures, active gates, and ODE dummy gate structures disposed around the active semiconductor structures, wherein a gate cut is disposed between P-type and N-type gate regions to reduce leakage current caused by an ODE dummy gate structure formed over the active semiconductor structures in an N-type active semiconductor region;

FIG. 6 is a flowchart illustrating an exemplary process of fabricating the circuit in FIGS. 4A-4C;

FIGS. 7A-1 and 7A-2 illustrate a top and cross-sectional side view, respectively, of a first exemplary fabrication stage of active semiconductor formation in the fabrication of the circuit in FIGS. 4A-4C according to the exemplary process in FIG. 6;

FIGS. 7B-1 and 7B-2 illustrate a top and cross-sectional side view, respectively, of a second exemplary fabrication stage of dummy gate formation in the circuit in FIGS. 4A-4C according to the exemplary process in FIG. 6;

FIGS. 7C-1 and 7C-2 illustrate a top and cross-sectional side view, respectively, of a third exemplary fabrication stage of source/drain formation and replacement metal gate formation to form active gates and ODE dummy gate structures with disposing of a dielectric structure of increased thickness in the area of the ODE dummy gate structure in the circuit in FIGS. 4A-4C according to the exemplary process in FIG. 6;

FIGS. 7D-1 and 7D-2 illustrate a top and cross-sectional side view, respectively, of a fourth exemplary fabrication stage of metal gate formation and interlayer dielectric deposition in the circuit in FIGS. 4A-4C according to the exemplary process in FIG. 6;

FIGS. 7E-1 and 7E-2 illustrate a top and cross-sectional side view, respectively, of a fifth exemplary fabrication stage of diffusion break formation in the circuit in FIGS. 4A-4C according to the exemplary process in FIG. 6;

FIG. 8 is a block diagram of an exemplary processor-based system that can include a circuit having a gate dielectric structure formed between a work function metal structure of an ODE dummy gate structure and an active semiconductor structure thicker than a gate dielectric structure formed between a work function metal structure and an active semiconductor structure of an active gate in the circuit to reduce leakage current, including but not limited to the circuit in FIGS. 4A-4C; and

FIG. 9 is a block diagram of an exemplary wireless communications device that includes radio frequency (RF) components formed from an integrated circuit (IC), wherein any of the components therein can include a circuit having a gate dielectric structure formed between a work function metal structure of an ODE dummy gate structure and an active semiconductor structure thicker than a gate dielectric structure formed between a work function metal structure and an active semiconductor structure of an active gate in the circuit to reduce leakage current, including but not limited to the circuit in FIGS. 4A-4C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include circuits employing on-diffusion (OD) edge (ODE) dummy gate structures in cell circuit with increased gate dielectric thickness to reduce leakage current. An integrated circuit (“circuit”) is provided that includes at least one active semiconductor region (also referred to as “diffusion region”) formed in a substrate. For example, the circuit can include a P-type active semiconductor region(s) and an N-type active semiconductor region(s) (e.g. diffusion regions) formed in a substrate to form complementary metal oxide semiconductor (CMOS) circuits. A diffusion barrier can be formed on an edge of the circuit to provide isolation between a cell circuit and an adjacent cell circuit formed on the substrate. One or more active semiconductor structures (e.g., a fin) of the cell circuit are formed in the active semiconductor regions to form semiconductor channels for field effect transistors (FETs). A plurality of gates are formed over the active semiconductor structures to provide gates for FETs and/or routing in a cell circuit. One or more of the gates are dummy gates that are ODE dummy gate structures formed over ends of the active semiconductor structure(s) at the edge of the cell circuit to provide an additional dummy gate pattern to protect an active gate during the fabrication of the circuit. Because the ODE dummy gate structures are disposed over ends of the active semiconductor structure, gaps may be present that are adjacent to the ends of the active semiconductor structures, allowing for an increased volume of work function metal structures to be formed for the ODE dummy gate structures and thus leading to leakage current. Opening and etching the ODE dummy gate structure area of the cell circuit when forming dummy gates in the cell circuit can cause the gate dielectric structure disposed on the active semiconductor structure to be damaged, thus reducing isolation between an ODE dummy gate structure and the active semiconductor structure. A reduced isolation between the ODE dummy gate structure and the active semiconductor structure can increase current leakage.

In this regard, in exemplary aspects disclosed herein, a gate dielectric structure formed between a work function metal structure of the ODE dummy gate structures and an active semiconductor structure in a cell circuit is provided to have an increased thickness. The gate dielectric structure is formed to be thicker (e.g., in a height direction) than a gate dielectric structure formed between a work function metal structure and an active gate(s) in the cell circuit. The ODE dummy gate structure may be a poly (metal gate) ODE (PODE) dummy gate structure as an example. Providing a gate dielectric structure of increased thickness between an ODE dummy gate structure and an active semiconductor structure can offset damage to the gate dielectric structure that provides isolation between the ODE dummy gate structure and the active semiconductor structure. Providing a gate dielectric structure of increased thickness between an ODE dummy gate structure and the active semiconductor structure can also reduce the gap area adjacent to ends of the active semiconductor structures and thus reduce the volume of work function metal structure formed in the gaps to further reduce leakage current.

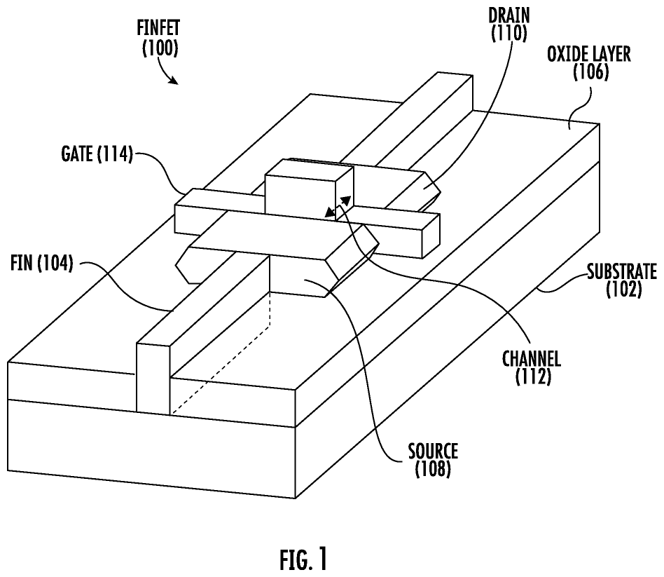

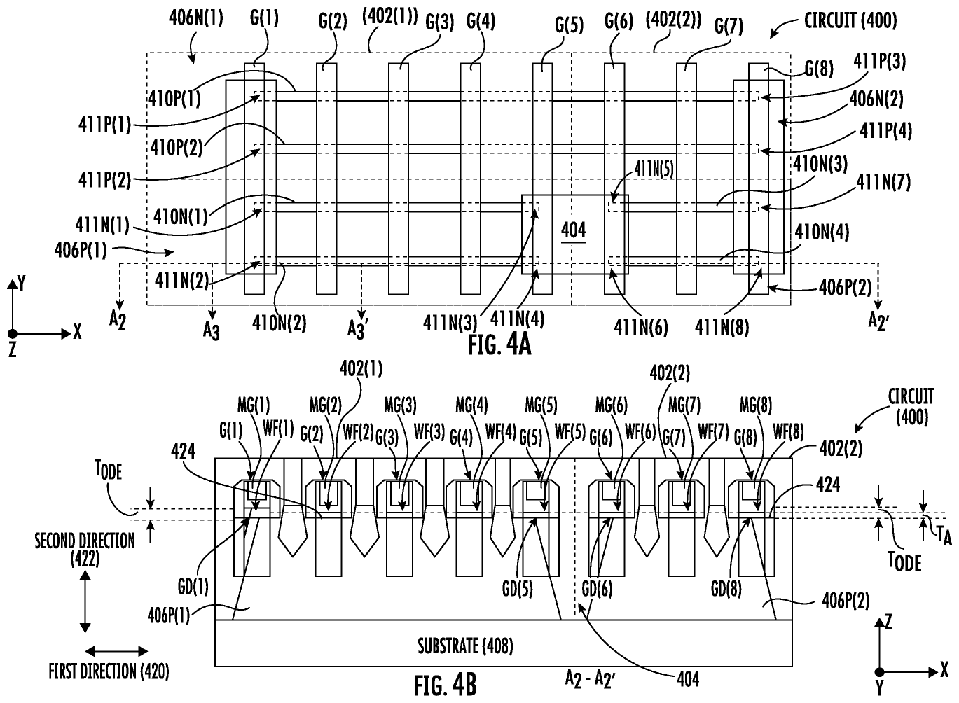

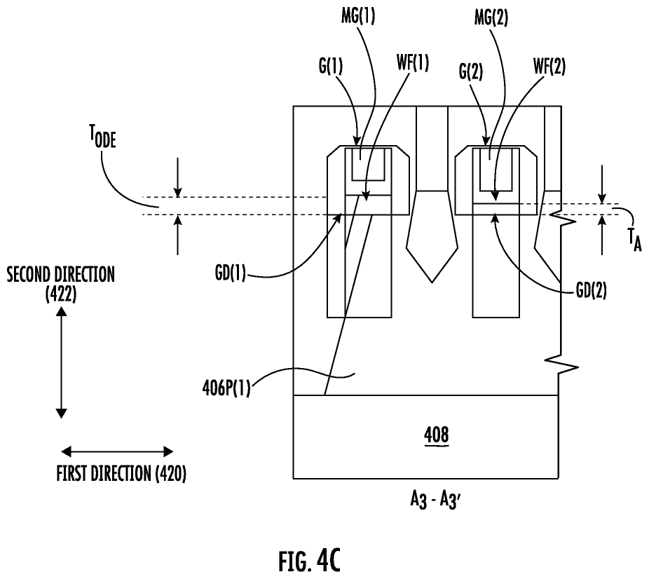

Before discussing circuits employing ODE dummy gate structures in a cell circuit with a gate dielectric of increased thickness to reduce leakage current starting at FIG. 4A, an exemplary transistor and CMOS circuit formed from such transistor that includes dummy as poly (metal gate) on-diffusion edge (PODE) structures to protect the ends of the active semiconductor structures to an active gate is first described with regard to FIGS. 1-3B.

To address the need to scale down channel lengths in transistors while avoiding or mitigating short channel effects (SCEs), transistor designs alternative to planar transistors have been developed. One such alternative transistor design includes a FinFET that provides a conducting channel via a “Fin” formed from a substrate. Material is wrapped around the Fin to form a gate of the FinFET. For example, FIG. 1 illustrates an exemplary FinFET 100. The FinFET 100 includes a substrate 102 and a Fin 104 formed above the substrate 102. The Fin 104 is formed from a semiconductor material. The Fin 104 may be formed from a semiconductor substrate 102 by lithography and etching processes to form raised Fins 104 from the semiconductor material of the substrate 102. An oxide layer 106 is included on either side of the Fin 104. The FinFET 100 includes a source 108 and a drain 110 interconnected by the Fin 104 such that an interior portion of the Fin 104 serves as a semiconductor channel 112 (“channel 112”) between the source 108 and drain 110. The Fin 104 is surrounded by a “wrap-around” gate 114. The wrap-around structure of the gate 114 provides better electrostatic control over the channel 112, and thus helps reduce leakage current and overcoming other SCEs.

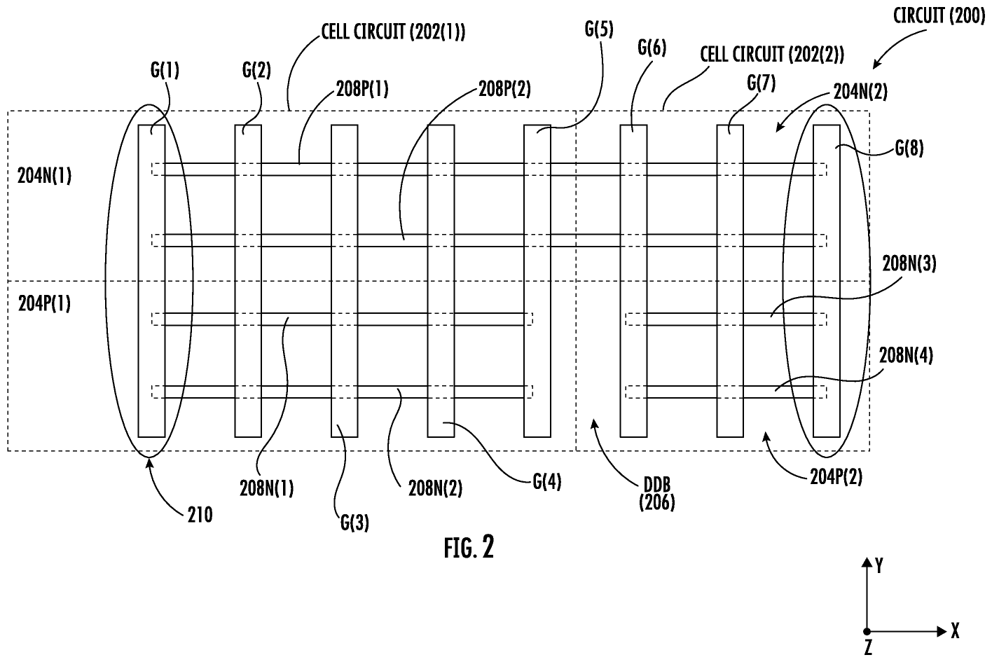

Transistors, such as FinFETs, can be used to form CMOS circuits in ICs. For example, FIG. 2 is a top view of a circuit 200 that includes adjacent cell circuits 202(1), 202(2), which are each an IC, that support the formation of semiconductor devices, such as the FinFET 100 in FIG. 1. The cell circuits 202(1), 202(2) include respective P-type well active semiconductor device regions (“P-type well device regions”) 204P(1), 204P(2) and N-type well active semiconductor device regions (“N-type well device regions”) 204N(1), 204N(2) formed in a semiconductor substrate 210 (“substrate”) to provide active well areas for forming semiconductor devices, such as transistors. For example, the semiconductor fin break area 210 can be doped with a P-type dopant to form the P-type well device regions 204P(1), 204P(2), and an N-type dopant to form the N-type well device regions 204N(1), 204N(2). The P-type well device regions 204P(1), 204P(2) and N-type well device regions 204N(1), 204N(2) call also be referred to as well regions. The N-type well device regions 204N(1), 204N(2) of the respective cell circuits 202(1), 202(2) are isolated from each other by a double diffusion break (DDB) 206. The cell circuits 202(1), 202(2) also include respective P-type semiconductor active structures 208P(1), 208P(2) and N-type semiconductor active structures 208N(1)-208N(4) extending in the X-axis direction. For example, the P-type and N-type semiconductor active structures 208P(1), 208P(2), 208N(1)-208N(4) may be semiconductor Fins, also known as “Fins” for forming three-dimensional (3D) active structures. The respective N-type semiconductor active structures 208N(1), 208N(2) and 208N(3), 208N(4) were originally formed as single semiconductor fin structures, but are isolated by the DDB 206.

Gates G(1)-G(8) are formed in the cell circuits 202(1), 202(2) and elongated in the direction of the Y-axis extending around at least a portion of the P-type and N-type semiconductor active structures 208P(1), 208P(2), 208N(1)-208N(4). Gates G(2)-G(4) and G(7) are active gates for semiconductor devices that surround the P-type and N-type semiconductor active structures 208P(1), 208P(2), 208N(1)-208N(4) to form active semiconductor structures of transistors. Gates G(2)-G(4) and G(7) may be metal gates. Gates G(1), G(5), G(6), and G(8) are dummy gates that are not used to form active gates of transistors. These dummy gates G(1), G(5), G(6), and G(8) are gate (metal gate) on-diffusion edge (PODE) structures formed to protect the ends of the P-type and N-type semiconductor active structures 208P(1), 208P(2), 208N(1)-208N(4) to provide an additional dummy patterned gate to protect an active gate during the fabrication of the circuit 200. Dummy gates G(1), G(5), G(6), and G(8) can be metal gates that are used for additional routing in the circuit 200 with a dielectric material disposed between the dummy gates G(1), G(5), G(6), and G(8) and the P-type and N-type semiconductor active structures 208P(1), 208P(2), 208N(1)-208N(4) to provide further isolation between adjacent cell circuits.

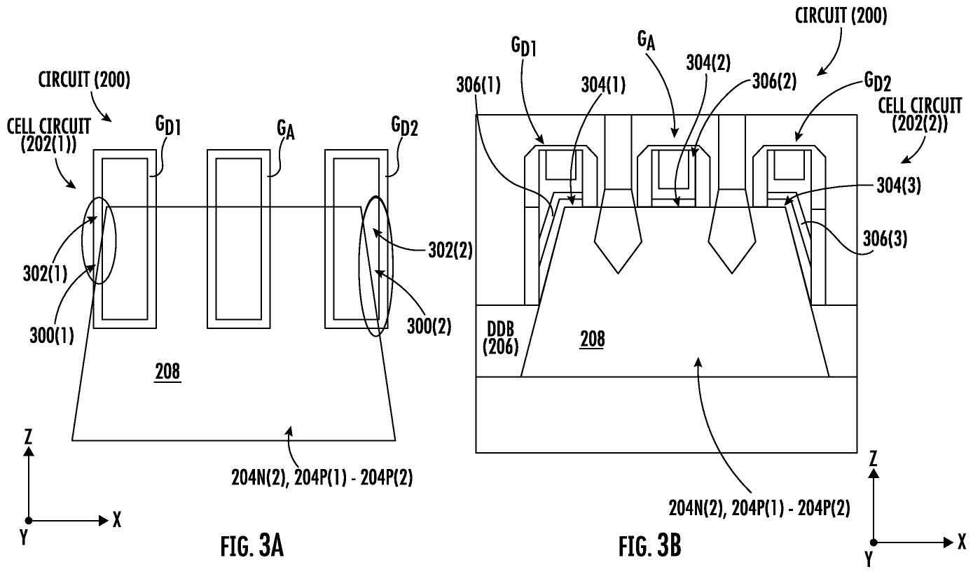

FIGS. 3A and 3B illustrate side views of a P-type and N-type well device regions 204N(2), 204P(1), or 204P(2) in a cell circuit that can be the cell circuit 202(1) or cell circuit 202(2) in the circuit 200 of FIG. 2 that illustrates an active gate G_{A} and PODE dummy gate structures G_{D1}, G_{D2} to protect ends 300(1), 300(2) of a semiconductor active structure 208 that provides a semiconductor channel. When the PODE dummy gate structures G_{D1}, G_{D2} are formed over a portion of the device region 204N(2), 204P(1), or 204P(2), this forms a dummy device that adds parasitic capacitance, resistance, and may cause undesired leakage current. Further, as shown as shown in FIG. 3A, because the PODE dummy gate structures G_{D1}, G_{D2} are disposed over the ends 300(1), 300(2) of the semiconductor active structure 208, gaps 302(1), 302(2) are present that are adjacent to the ends 300(1), 300(2). Thus, as shown in another side view of a well device region 204N(2), 204P(1), or 204P(2) in a cell circuit 202(1), 202(2) in FIG. 3B, when gate dielectric material 304(1)-304(3) (e.g., a gate oxide) and work function metal structures 306(1)-306(3) are formed for the gates G_{A}, G_{D1}, G_{D2}, gate dielectric material 304(1), 304(3) and work function metal structures 306(1), 306(3) are formed in the gaps 302(1), 302(2). This can further contribute to undesired leakage current. Further, each opening and etching of work function metal structure in the area of the PODE dummy gate structures G_{D1}, G_{D2} that may occur due to the formation of different voltage threshold types of FETs in different areas of the circuit 200 can further reduce the thickness of the gate dielectric material 304(1), 304(3), thus causing additional work function metal structures 306(1), 306(3) to be present in the respective PODE dummy gate structures G_{D1}, G_{D2}, further increasing leakage current.

In this regard, FIGS. 4A-4C are respective top and cross-sectional side views of an exemplary circuit 400 that includes adjacent cell circuits 402(1), 402(2) employing ODE dummy gate structures with a gate dielectric of increased thickness to reduce leakage. FIG. 4B is a cross-sectional side view of the circuit 400 in FIG. 4A along an A₂-A₂′ line. FIG. 4C is a close-up cross-sectional side view of the circuit 400 in FIG. 4A along the cross-sectional break line A₃-A₃′ line. The circuit 400 is fabricated according to the layout of a circuit cell, which is a pre-defined layout of components that are commonly used to fabricate semiconductor circuits, including, but not limited to, active semiconductor regions, gates, active semiconductor structures, and metal interconnect lines according to design parameters, including area and node size. In this manner, the circuit cells can facilitate repeated fabrication of circuits in a semiconductor wafer or die.

As shown in FIG. 4A, the cell circuits 402(1), 402(2) in this example are fabricated according to a circuit cell that includes both respective P-type doped active semiconductor regions 406P(1), 406P(2) (“P-type active semiconductor regions 406P(1), 406P(2)”) and N-type doped active semiconductor regions 406N(1), 406N(2) (“N-type active semiconductor regions 406N(1), 406N(2)”). Including P-type active semiconductor regions 406P(1), 406P(2) and N-type active semiconductor regions 406N(1), 406N(2) in the circuit 400 allows the fabrication of P-type and N-type FETs, such as to form complementary metal-oxide semiconductor (CMOS) circuits. The N-type active semiconductor regions 406N(1), 406N(2) are formed in the circuit 400 according to a circuit cell as one active semiconductor region, but are isolated by a diffusion barrier 404. The diffusion barrier 404 may be a shallow trench isolation (STI) structure for example. The diffusion barrier 404 is disposed outside of the N-type active semiconductor regions 406N(1), 406N(2). The cell circuits 402(1), 402(2) include a layout in the X-axis in a first direction 420 and in the Y-axis in a second direction 422 orthogonal to the X-axis. The cell circuits 402(1), 402(2) include the respective P-type active semiconductor regions 406P(1), 406P(2) and N-type active semiconductor regions 406N(1), 406N(2) formed in a substrate 408, as shown in FIGS. 4B and 4C, to provide active areas for forming semiconductor devices, such as transistors.

The P-type active semiconductor regions 406P(1), 406P(2) and N-type active semiconductor regions 406N(1), 406N(2) include respective P-type semiconductor structures 410P(1), 410P(2) and N-type semiconductor fin structures 410N(1)-410N(4) formed from a semiconductor material. The P-type semiconductor structures 410P(1), 410P(2) and N-type semiconductor structures 410N(1)-410N(4) are fabricated according to a uniform layout to avoid non-uniformities in performance of semiconductor structures formed in the P-type semiconductor structures 410P(1), 410P(2) and N-type semiconductor structures 410N(1)-410N(4). As an example, the P-type and N-type semiconductor structures 410P(1), 410P(2), 410N(1)-410N(4) may be semiconductor Fins, also known as “Fins” for forming three-dimensional (3D) active structures that can include source and drain structures. A gate can be disposed adjacent to the fin between a formed source and drain to form a channel region between the formed source and drain in the fin. The respective N-type semiconductor structures 410N(1), 410N(2) and 410N(3), 410N(4) were originally formed as a single semiconductor source/drain structure, but are isolated by the diffusion barrier 404.

The cell circuits 402(1), 402(2) each have respective active gates G(2)-G(4) and G(7) and ODE dummy gate structures G(1), G(5), G(6), and G(8) (e.g., a poly (metal gate) ODE (PODE) dummy gate structure) disposed above semiconductor structures 410P(1), 410P(2), 410N(1)-410N(4) for forming semiconductor devices. The ODE dummy gates structures G(1), G(5), G(6), and G(8) are dummy gates formed over ends 411P(1)-411P(4), 411N(1)-411N(8) of the semiconductor structures 410P(1), 410P(2), 410N(1)-410N(4) at the edge of the cell circuits 402(1), 402(2) to provide additional pattern protection of work gates during the fabrication of the circuit 400. In this example, the ODE dummy gate structures G(5) and G(6) are disposed adjacent to the diffusion barrier 404. If the circuit 400 is intended to include three-dimensional (3D) transistors, such as FinFETs or GAA FETs, the active gates G(2)-G(4) and G(7) may be disposed around at least a portion of the semiconductor structures 410P(1), 410P(2), 410N(1)-410N(4) for improved channel control. In the case of a FinFET, the semiconductor structures 410P(1), 410P(2), 410N(1)-410N(4) may be structures. The active gates G(2)-G(4) and G(7) may be disposed around the entire semiconductor structures 410P(1), 410P(2), 410N(1)-410N(4) when forming a GAA FET. In this case, the semiconductor structures 410P(1), 410P(2), 410N(1)-410N(4) may be nanostructures, such as nanowires, nanoslabs, or nanosheets as examples. The separate cell circuits 402(1), 402(2) are formed in the circuit 400 as a result of including the diffusion barrier 404 in the circuit 400 that isolates regions of the circuit 400. For example, the diffusion barrier 404 may be included if a design calls for a different bias voltage to be applied to devices formed in each of the cell circuits 402(1), 402(2).

Because the ODE dummy gate structures G(1), G(5), G(6), and G(8) are disposed over the ends 411P(1)-411P(4), 411N(1)-411N(8) of the semiconductor structures 410P(1), 410P(2), 410N(1)-410N(4), gaps may be present that are adjacent to the ends 411P(1)-411P(4), 411N(1)-411N(8) of the semiconductor structures 410P(1), 410P(2), 410N(1)-410N(4) allowing for an increased volume of work function metal structures to be formed for the ODE dummy gate structures G(1), G(5), G(6), and G(8) and thus leading to leakage current. Opening and etching the ODE dummy gate structure G(1), G(5), G(6), G(8) areas of the cell circuits 402(1), 402(2) when forming gates in the circuit 400 can cause the gate dielectric structure disposed on the semiconductor structures 410P(1), 410P(2), 410N(1)-410N(4) to be damaged, thus reducing isolation between an ODE dummy gate structure G(1), G(5), G(6), and G(8) and the semiconductor structures 410P(1), 410P(2), 410N(1)-410N(4). A reduced isolation between the ODE dummy gate structure G(1), G(5), G(6), and G(8) and the semiconductor structure 410P(1), 410P(2), 410N(1)-410N(4) can increase current leakage.

As shown in FIG. 4B and discussed in more detail below, a gate dielectric structure GD(1), GD(5), GD(6), and GD(8) is formed between a work function metal structure WF(1), WF(5), WF(6), and WF(8) of the ODE dummy gate structures G(1), G(5), G(6), and G(8) and active semiconductor structures 410N(1)-410N(4). For example, the gate dielectric structures GD(1), GD(5), GD(6), and GD(8) may be formed from an oxide material. A gate dielectric structure GD(2)-GD(4) and GD(7) is also formed between a work function metal structure WF(2)-WF(4) and WF(7) and active semiconductor structures 410N(1)-410N(4) of the active gates G(2)-G(4) and G(7). For example, the gate dielectric structures GD(2)-GD(4) and GD(7) may be formed from an oxide material. Metal gates MG(1)-MG(8) are included in the ODE dummy gate structures G(1), G(5), G(6), and G(8) and the active gates G(2)-G(4) and G(7). The ODE dummy gate structures G(1), G(5), G(6), and G(8) include metal gates MG(1), MG(5), MG(6), and MG(8) so that the ODE dummy gate structures G(1), G(5), G(6), and G(8) can be used for additional circuit routing. The work function metal structures WF(2)-WF(4) and WF(7) are structures of metal material disposed between a metal material for metal gates MG(2)MG(4), and MG(7) and the gate dielectric structures GD(2)-GD(4) and GD(7). Work function is the minimum quantity of energy required to remove an electron from the surface of a given solid, usually a metal. A work function is a metal with a higher work function than a gate dielectric and a lower work function than a metal gate. A work function metal, including work function metal structures WF(2)-WF(4) and WF(7), is selected based on the desired work function for a semiconductor device formed with a gate that includes a metal gate and a work function metal. The work function metal of the gate is selected to control a threshold voltage to activate a channel of a semiconductor device formed by disposing a gate adjacent to the active semiconductor structure between a source and drain formed in the active semiconductor structure.

As shown in FIG. 4B, the gate dielectric structure GD(1), GD(5), GD(6), and GD(8) for the ODE dummy gate structures G(1), G(5), G(6), and G(8) are provided to be thicker than the gate dielectric structures GD(2)-GD(4) and GD(7) of the active gates G(2)-G(4) and G(7). This is to reduce leakage current since the ODE dummy gate structures G(1), G(5), G(6), and G(8) have metal gates MG(1), MG(5), MG(6), and MG(8) that can activate the active semiconductor structures 410P(1), 410P(2), 410N(1)-410N(4) if not well isolated from the active semiconductor structures 410P(1), 410P(2), 410N(1)-410N(4), because the ODE dummy gate structures G(1), G(5), G(6), and G(8) are used for circuit routing. For example, the thickness of gate dielectric structures GD(2)-GD(4) and GD(7) of the active gates G(2)-G(4) and G(7) is shown as T_{A} in the second direction 422 in the active semiconductor structures 410P(1), 410P(2), 410N(1)-410N(4), whereas the thickness of the gate dielectric structures GD(1), G(5), GD(6), and G(8) of the ODE dummy gate structures G(1), G(5), G(6) and G(8) is shown as T_{ODE} in the second direction 422 above a first, top surface 424 the active semiconductor structures 410P(1), 410P(2), 410N(1)-410N(4). To illustrate further detail on the differences in thicknesses T_{ODE}, T_{A} of gate dielectric structures, FIG. 4C is provided. FIG. 4C is a close-up cross-sectional side view across the cross-sectional break line A₃-A₃′ in FIG. 4A of the gate dielectric structures GD(1), GD(2) of the respective ODE dummy gate structure G(1) and active gate G(2). FIG. 4C further illustrates the difference in thickness T_{ODE} of gate dielectric structure GD(1) of ODE dummy gate structure G(1) versus the thickness T_{A} of gate dielectric structure GD(2) of active gate G(2).

As examples, the thickness T_{A} of gate dielectric structures GD(2)-GD(4) and GD(7) of the active gates G(2)-G(4) and G(7) may be between 0.7 nanometers (nm) and 1.5 nm. The thickness T_{ODE} of the gate dielectric structures GD(1), GD(5), GD(6), and GD(8) of the ODE dummy gate structures G(1), G(5), G(6) and G(8) may be between 2.0 nm and 3.5 nm. As another example, the ratio of thickness T_{ODE} of the gate dielectric structures GD(1), GD(5), GD(6), and GD(8) of the ODE dummy gate structures G(1), G(5), G(6) and G(8) to the thickness T_{A} of gate dielectric structures GD(2)-GD(4) and GD(7) of the active gates G(2)-G(4) and G(7) may be at least 2.0 and between 2.0 to 3.0.

Providing a gate dielectric structure GD(1), GD(5), GD(6), and GD(8) of increased thickness to isolate the ODE dummy gate structures G(1), G(5), G(6), and G(8) from the active semiconductor structures 410P(1), 410P(2), 410N(1)-410N(4) can reduce damage to the gate dielectric structures GD(1), GD(5), GD(6), and GD(8) providing isolation between the ODE dummy gate structures G(1), G(5), G(6), and G(8) and the active semiconductor structures 410P(1), 410P(2), 410N(1)-410N(4). Providing a gate dielectric structure GD(1), GD(5), GD(6), and GD(8) of increased thickness between the ODE dummy gate structures G(1), G(5), G(6), and G(8) and the active semiconductor structures 410P(1), 410P(2), 410N(1)-410N(4) can also reduce the gap area adjacent to the ends 411P(1)-411P(4), 411N(1)-411N(8) of the active semiconductor structures 410P(1), 410P(2), 410N(1)-410N(4) and thus reduce the volume of work function metal structures WF(1), WF(5), WF(6), and WF(8) formed in the gaps to further reduce leakage current.

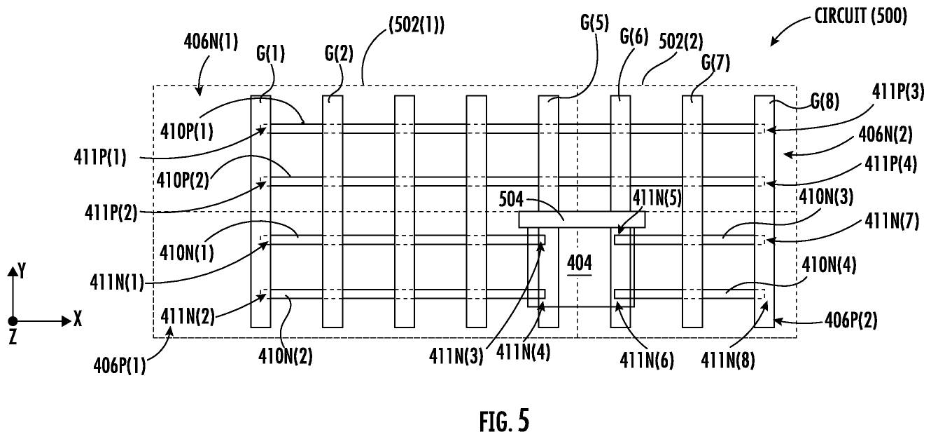

As an example, providing gate dielectric structures GD(1), GD(5), GD(6), and GD(8) of increased thickness between the ODE dummy gate structures G(1), G(5), G(6), and G(8) and the active semiconductor structures 410P(1), 410P(2), 410N(1)-410N(4) can avoid the need to provide a gate cut as shown in FIG. 5. FIG. 5 is a top view of an exemplary circuit 500 that includes adjacent cell circuits 502(1), 502(2) that include the same structures are provided in the cell circuits 402(1), 402(2) in FIGS. 4A and 4B, except that the gate dielectric structures GD(1), GD(5), GD(6), and GD(8) between the ODE dummy gate structures G(1), G(5), G(6), and G(8) and the active semiconductor structures 410P(1), 410P(2), 410N(1)-410N(4) are not necessarily thicker than the gate dielectric structures GD(2)-GD(4) and GD(7) of the active gates G(2)-G(4) and G(7). However, to isolate ODE dummy gate structures G(1), G(5), G(6), and G(8) from the active semiconductor structures 410N(1)-410N(4), a gate cut 504 is provided in the ODE dummy gate structures G(5) and G(6) to isolate the ODE dummy gate structures G(5) and G(6) from each other in the respective P-type active semiconductor region 406P(1), 406P(2) from the respective N-type active semiconductor regions 406N(1), 406N(2). However, this means that the ODE dummy gate structures G(5) and G(6) in the N-type active semiconductor regions 406N(1), 406N(2) are isolated from the ODE dummy gate structures G(5) and G(6) in the P-type active semiconductor regions 406P(1), 406P(2) and cannot be used for routing signals from the devices formed in the P-type active semiconductor regions 406P(1), 406P(2) in the cell circuits 502(1), 502(2).

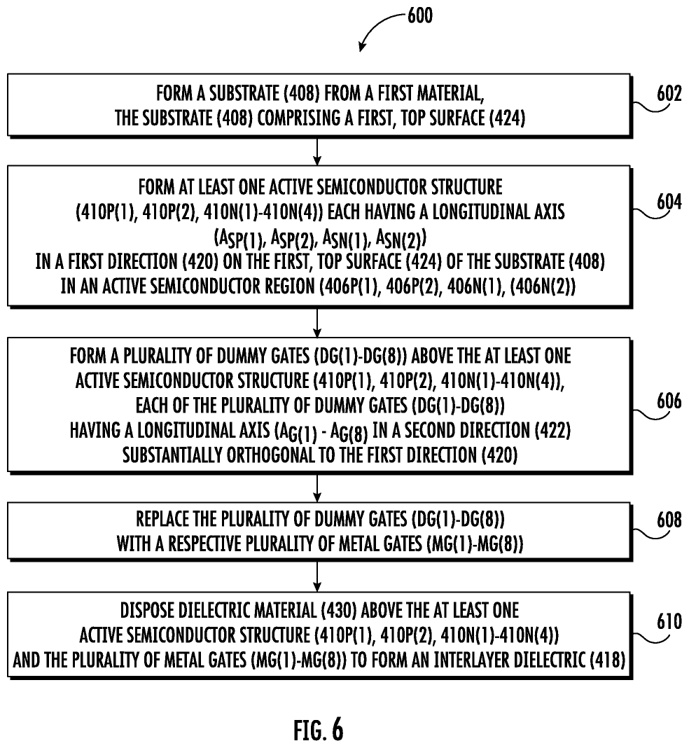

FIG. 6 is a flowchart illustrating an exemplary process 600 of fabricating the circuit 400 in FIGS. 4A-4C. The process 600 in FIG. 6 will be discussed in conjunction with exemplary fabrication stages 700(1)-700(5) in FIGS. 7A-1-7E-2.

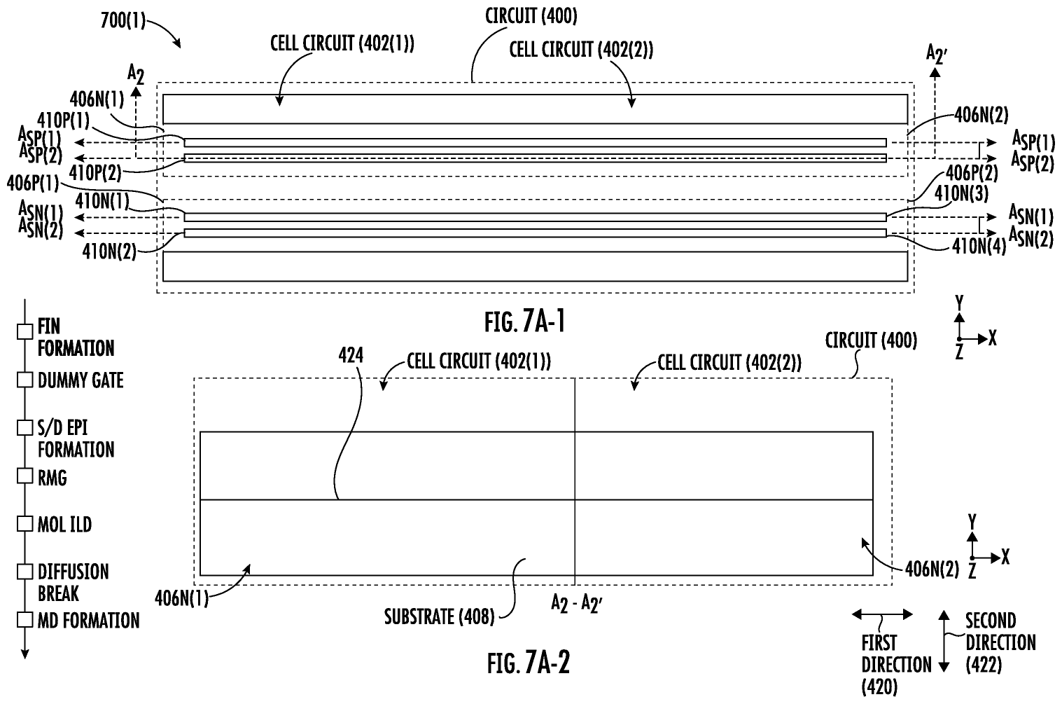

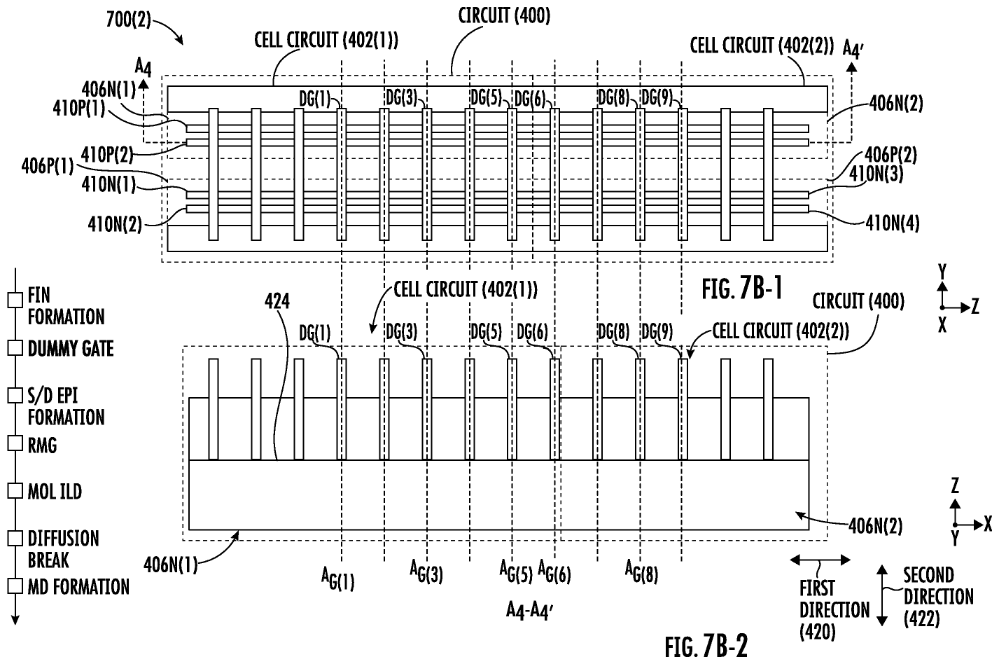

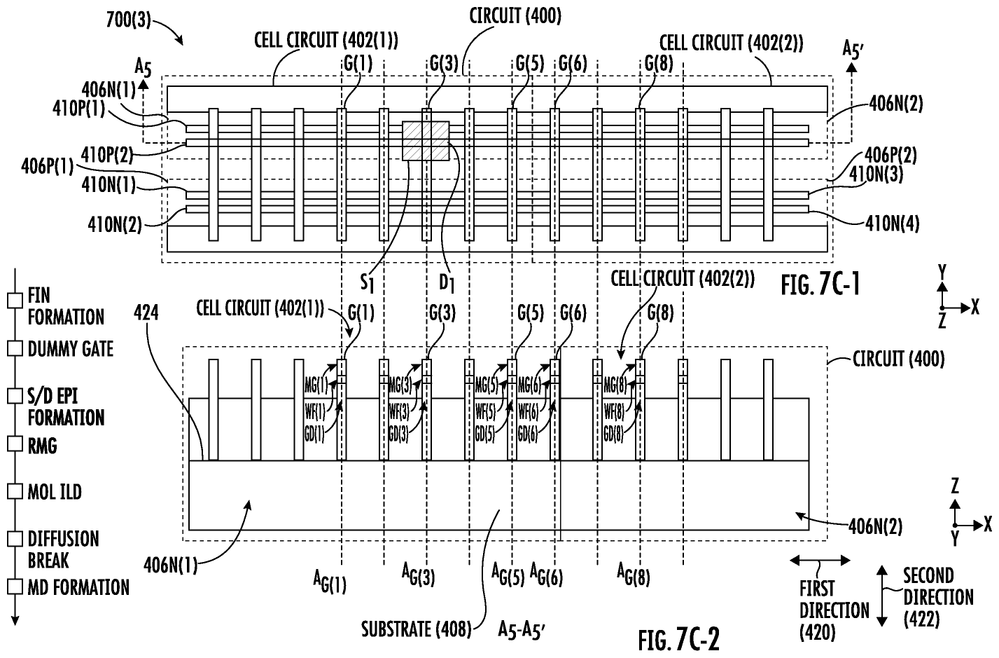

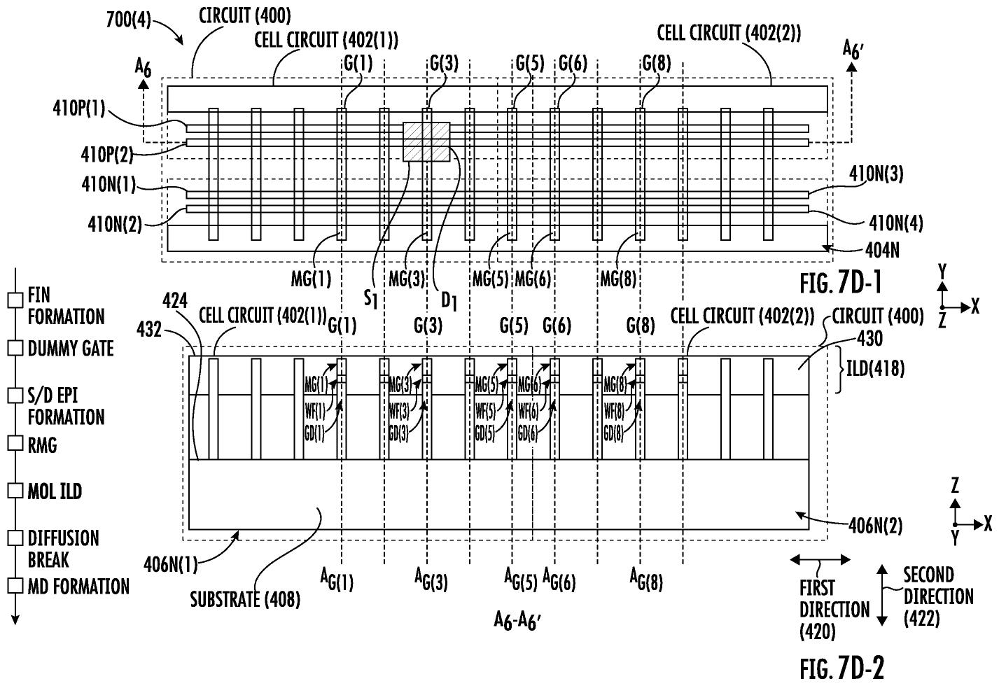

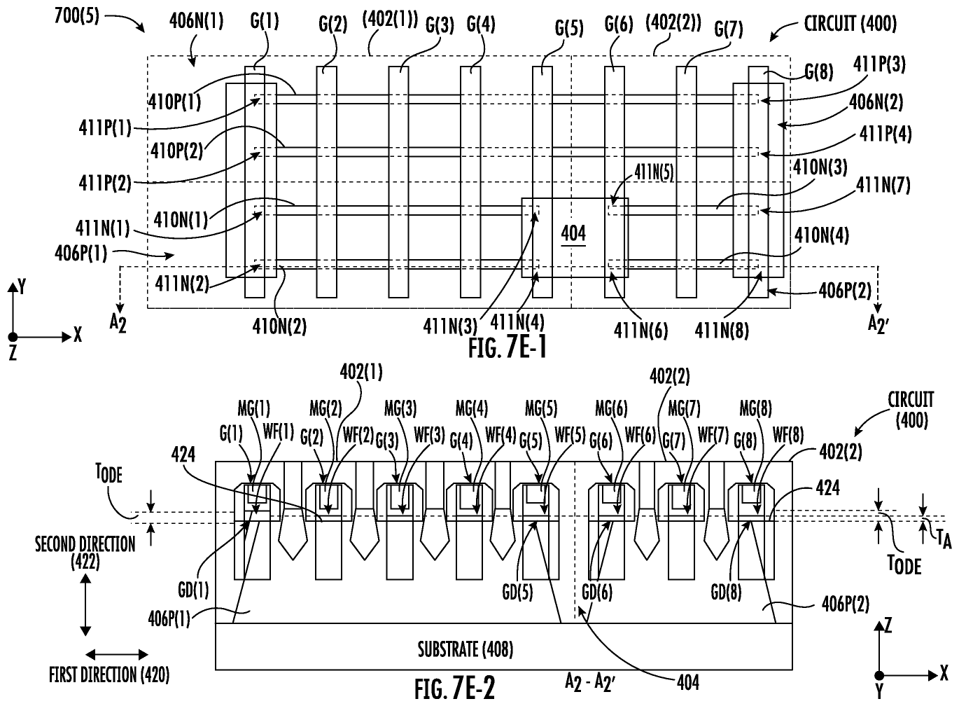

In this regard, with reference to FIG. 6, a first exemplary step in the process 600 of fabricating the circuit 400 in FIGS. 4A-4C is to form the substrate 408 from a first material, wherein the substrate 408 comprises the first, top surface 424 (block 602). This is shown by example in the fabrication stage 700(1) in FIGS. 7A-1 and 7A-2. FIG. 7A-1 is a top view of the fabrication stage 700(1) of the circuit 400 in FIGS. 4A-4C. FIG. 7A-2 is a cross-sectional side view of the fabrication stage 700(1) of the circuit 400 across cross-sectional break line A₂-A₂′ in FIG. 7A-1. Common element structures between the fabrication stage 700(1) of the circuit 400 and the circuit 400 in FIGS. 4A-4C are shown with common element numbers and thus will not be re-described. As also shown in FIGS. 7A-1 and 7A-2, the fabrication stage 700(1) of the circuit 400 includes the formation of the P-type and N-type active semiconductor structures 410P(1), 410P(2), 410N(1)-410N(4) each having the longitudinal axis A_{SP(1)}, A_{SP(2)}, A_{SN(1)}, A_{SN(2)} in the first direction 420 on the first, top surface 424 of the substrate 408 in a P-type and N-type active semiconductor region 406P(1), 406P(2), 406N(1), 406N(2) (block 604 in FIG. 6). As a non-limiting example, the P-type and N-type semiconductor structures 410P(1), 410P(2), 410N(1)-410N(4) may have been formed by disposing a semiconductor material on the substrate 408 and applying a mask that has a pattern of the P-type and N-type semiconductor structures 410P(1), 410P(2), 410N(1)-410N(4) as part of a lithography process. A photoresist material layer could be disposed over the semiconductor material disposed on the substrate 408 and a mask could be applied and exposed to form openings where it is desired to etch away portions of the semiconductor material to leave the P-type and N-type semiconductor structures 410P(1), 410P(2), 410N(1)-410N(4). The portions of the semiconductor material below the openings can be etched and the photoresist layer can be removed.

With continuing reference to FIG. 6, a next exemplary step in the process 600 of fabricating the circuit 400 in FIGS. 4A-4C is forming a plurality of dummy gates DG(1)-DG(8) (e.g., poly dummy gates) above the P-type and N-type semiconductor structures 410P(1), 410P(2), 410N(1)-410N(4) (block 606 in FIG. 6). This is shown by example in the fabrication stage 700(2) in FIGS. 7B-1 and 7B-2. FIG. 7B-1 illustrates a top view of the exemplary second fabrication stage 700(2) of the circuit 400 in FIGS. 4A-4C of dummy gate formation. FIG. 7B-2 is a cross-sectional side view of the fabrication stage 700(2) of the circuit 400 across cross-sectional break line A₄-A₄′ in FIG. 7B-1. As shown in FIGS. 7B-1 and 7B-2, each of the dummy gates DG(1)-DG(8) has a longitudinal axis A_{G(1)}-A_{G(8)} in the second direction 422 substantially orthogonal to the first direction 420. The dummy gates DG(1)-DG(8) may be a dielectric material. The dummy gates DG(1)-DG(8) are formed to allow spacers to be formed around the dummy gates DG(1)-DG(8) in a subsequent processing step to form openings therebetween to allow a metal material to be filled in the openings to form metal gates G(1)-G(8) as shown in FIGS. 7C-1 and 7C-2.

With continuing reference to FIG. 6, a next exemplary step in the process 600 of fabricating the circuit 400 in FIGS. 4A-4C is forming sources S and drains D in portions of the P-type and N-type semiconductor structures 410P(1)-410P(2), 410N(1)-410N(4) where active semiconductor devices will be formed. This is shown by example in the fabrication stage 700(3) in FIGS. 7C-1 and 7C-2. FIG. 7C-1 illustrates a top view of the exemplary third fabrication stage 700(3) of the circuit 400 in FIGS. 4A-4C of source/drain formation in the circuit 400 in FIGS. 4A-4C. FIG. 7C-2 is a cross-sectional side view of the third fabrication stage 700(3) of the circuit 400 across cross-sectional break line A₅-A₅′ in FIG. 7C-1. As shown in FIGS. 7C-1 and 7C-2, an exemplary source S₁ and drain D₁ are shown as being formed in the P-type semiconductor structures 410P(1) and/or 410P(2) disposed on a first side and a second side opposite the first side of adjacent to the metal gate G(3), which replaced the dummy gate DG(3) in FIGS. 7B-1 and 7B-2. The dummy gate DG(3) is replaced with an active metal gate MG(3) to form a FET, such as a FinFET or gate-all-around (GAA) FET. The active gate MG(3) is disposed above and around the P-type semiconductor structures 410P(1) and/or 410P(2) to form a P-type FET as a FinFET or GAA FET. Sources and drains can also be formed adjacent to N-type semiconductor structures 410N(1)-410N(4) to form a N-type FET (NFET). For example, the source S₁ and drain D₁ could be epitaxially grown. For example, epitaxial growth of Phosphorous doped Silicon (SiP), Carbon Phosphorous doped Silicon (SiCP), or Phosphorous doped Germanium (GeP) may form regrown source/drain regions in the N-type active semiconductor regions 406N(1), 406N(2). Similarly, epitaxial growth of Boron doped Silicon Germanium (SiGeB), or Boron doped Germanium (GeB) may form regrown source/drain regions in the P-type active semiconductor regions 406P(1), 406P(2). As another example, the source S₁ and drain D₁ could be implanted in an implantation process.

With continuing reference to FIG. 6, a next exemplary step in the process 600 of fabricating the circuit 400 in FIGS. 4A-4C is replacing the dummy gates DG(1)-DG(8) (e.g., poly dummy gates) in the fabrication stage 700(2) in FIGS. 7B-1 and 7B-2 with metal gates MG(1)-MG(8) (block 608 in FIG. 6). This is also shown by example in the fabrication stage 700(3) in FIGS. 7C-1 and 7C-2. As shown in FIGS. 7C-1 and 7C-2, each of the dummy gates DG(1)-DG(8) in FIGS. 7B-1 and 7B-2 have been replaced by metal gates MG(1)-MG(8), each having a longitudinal axis A_{G(1)}-A_{G(8)} in the second direction 422 substantially orthogonal to the first direction 420. The metal gates MG(1)-MG(8) may be formed from a metal fill material formed to allow spacers to be formed around the dummy gates DG(1)-DG(8) in a subsequent processing step to form openings therebetween to allow a metal material to be filled in the openings, to form the metal gates MG(1)-MG(8). As previously discussed, metal gates MG(1), MG(5), MG(6), and MG(8) are ODE dummy gate structures, and metal gates MG(2)-MG(4) and MG(7) are active gates.

The replacement of dummy gates DG(1)-DG(8) with metal gates MG(1)-MG(8) (block 608 in FIG. 6) includes disposing a gate dielectric structure GD(1)-GD(8) in the P-type and N-type active semiconductor regions 406P(1), 406P(2), 406N(1), 406N(2) in the areas of dummy gates DG(1)-DG(8). A first gate dielectric structure GD(1)-GD(8) having a first thickness T_{A} above the first, top surface 424 of the active semiconductor structures 410P(1)-410P(2), 410N(1)-410N(4) as shown in FIGS. 4B and 4C. As shown in FIGS. 4B and 4C increase the thickness of the gate dielectric structure for the dummy gates DG(1), DG(5), DG(6), and DG(8) that will become ODE dummy gate structures G(1), G(5), G(6), and G(8), a second gate dielectric structure GD₂(1), GD₂(5)-GD₂(6), and GD₂(8) is disposed in the ODE dummy gate structure region on the gate dielectric structure GD(1)-GD(8) above the ends 411P(1)-411P(4), 411N(1)-411N(8) of the respective active semiconductor structures 410P(1), 410P(2), 410N(1)-410N(4) such that the first gate dielectric structures GD(1), GD₁(5), GD₁(6), and GD₁(8) and second gate dielectric structures GD₂(1), GD₂(5), GD₂(6), and GD₂(8) form the ODE dummy gate dielectric structures GD(1), GD(5), GD(6), and GD(8) having a second thickness T_{ODE} greater than the first thickness T_{A} of the first gate dielectric structures GD₁(2)-GD₁(4), and GD(7). The process also includes disposing the work function metal structures WF(1)-WF(8) on the respective gate dielectric structures GD(1)-GD(8), and disposing the metal gates MG(1)-MG(8) on the work function metal structures WF(1)-WF(8).

With continuing reference to FIG. 6, a next exemplary step in the process 600 of fabricating the circuit 400 in FIGS. 4A-4C is disposing dielectric material 430 above the P-type and N-type semiconductor structures 410P(1), 410P(2), 410N(1)-410N(4) and the gates G(1)-G(8) in this example to form an interlayer dielectric (ILD) 418, the interlayer dielectric 418 comprising a top surface 432 (block 610 in FIG. 6). This is shown by example in the fabrication stage 700(4) in FIGS. 7D-1 and 7D-2. FIG. 7D-1 illustrates a top view of the exemplary fourth fabrication stage 700(4) of the circuit 400 in FIGS. 4A-4C after the interlayer dielectric 418 has been formed above the P-type and N-type semiconductor structures 410P(1), 410P(2), 410N(1)-410N(4) and the gates G(1)-G(8) of the circuit 400. FIG. 7D-2 is a cross-sectional side view of the fabrication stage 700(4) of the circuit 400 across cross-sectional break line A₆-A₆′ in FIG. 7D-1. FIGS. 7E-1 and 7E-2 show the completed circuit 400 in FIGS. 4A-4C.

Circuits having a gate dielectric structure formed between a work function metal structure of an ODE dummy gate structure and an active semiconductor structure thicker than a gate dielectric structure formed between a work function metal structure and an active semiconductor structure of an active gate in the circuit to reduce leakage current, including but not limited to the circuits in FIGS. 4A-4C, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

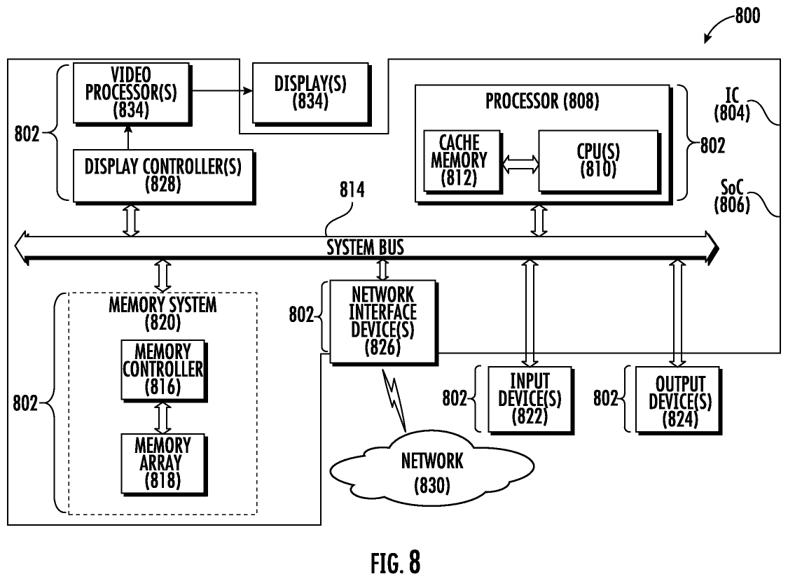

In this regard, FIG. 8 illustrates an example of a processor-based system 800 that can include circuits 802 having a gate dielectric structure formed between a work function metal structure of an ODE dummy gate structure and an active semiconductor structure thicker than a gate dielectric structure formed between a work function metal structure and an active semiconductor structure of an active gate in the circuit 802 to reduce leakage current, including but not limited to the circuits 400 in FIGS. 4A-4C, and according to any aspects disclosed herein. In this example, the processor-based system 800 may be formed as an IC 804 in a system-on-a-chip (SoC) 806. The processor-based system 800 includes a processor 808 that includes one or more central processor units (CPUs) 810, which may also be referred to as CPU or processor cores. The processor 808 may have cache memory 812 coupled to the processor(s) 808 for rapid access to temporarily stored data. As an example, the cache memory 812 could include circuits 802 having a gate dielectric structure formed between a work function metal structure of an ODE dummy gate structure and an active semiconductor structure thicker than a gate dielectric structure formed between a work function metal structure and an active semiconductor structure of an active gate in the circuit 802 to reduce leakage current, including but not limited to the circuits in FIGS. 4A-4C, and according to any aspects disclosed herein. The processor 808 is coupled to a system bus 814 and can intercouple master and slave devices included in the processor-based system 800. As is well known, the processor 808 communicates with these other devices by exchanging address, control, and data information over the system bus 814. For example, the processor 808 can communicate bus transaction requests to a memory controller 816 as an example of a slave device. Although not illustrated in FIG. 8, multiple system buses 814 could be provided, wherein each system bus 814 constitutes a different fabric.

Other master and slave devices can be connected to the system bus 814. As illustrated in FIG. 8, these devices can include a memory system 820 that includes the memory controller 816 and a memory array(s) 818, one or more input devices 822, one or more output devices 824, one or more network interface devices 826, and one or more display controllers 828, as examples. Each of the memory system 820, the one or more input devices 822, the one or more output devices 824, the one or more network interface devices 826, and the one or more display controllers 828 can include circuits 802 having a gate dielectric structure formed between a work function metal structure of an ODE dummy gate structure and an active semiconductor structure thicker than a gate dielectric structure formed between a work function metal structure and an active semiconductor structure of an active gate in the circuit 802 to reduce leakage current, including but not limited to the circuits 400 in FIGS. 4A-4C, and according to any aspects disclosed herein. The input device(s) 822 can include any type of input device, including, but not limited to, input keys, switches, voice processors, etc. The output device(s) 824 can include any type of output device, including, but not limited to, audio, video, other visual indicators, etc. The network interface device(s) 826 can be any device configured to allow exchange of data to and from a network 830. The network 830 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 826 can be configured to support any type of communications protocol desired.

The processor 808 may also be configured to access the display controller(s) 828 over the system bus 814 to control information sent to one or more displays 832. The display controller(s) 828 sends information to the display(s) 832 to be displayed via one or more video processors 834, which process the information to be displayed into a format suitable for the display(s) 832. The display(s) 832 can include any type of display, including, but not limited to, a cathode ray tube (CRT), a liquid crystal display (LCD), a plasma display, a light emitting diode (LED) display, etc. The display controller(s) 828, display(s) 832, and/or the video processor(s) 834 can include circuits 802 having a gate dielectric structure formed between a work function metal structure of an ODE dummy gate structure and an active semiconductor structure and according to any aspects disclosed herein, and according to any aspects disclosed herein.

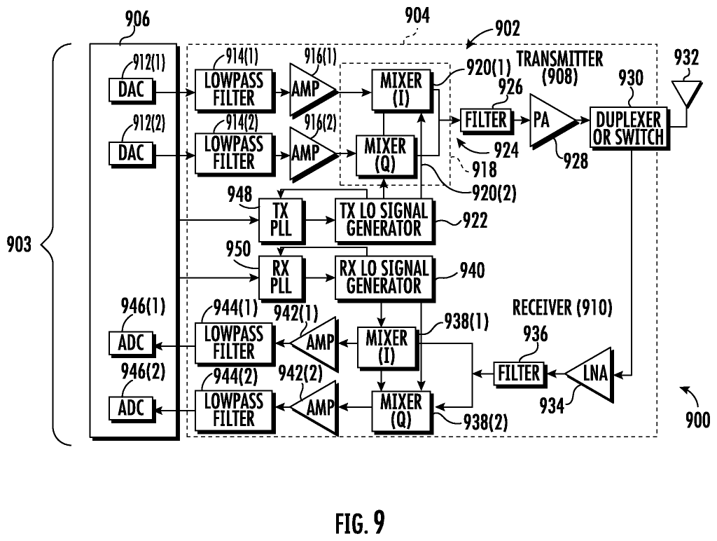

FIG. 9 illustrates an exemplary wireless communications device 900 that includes radio frequency (RF) components formed from an IC 902, wherein any of the components therein can include circuits 903 having a gate dielectric structure formed between a work function metal structure of an ODE dummy gate structure and an active semiconductor structure and according to any aspects disclosed herein. The wireless communications device 900 may include or be provided in any of the above referenced devices, as examples. As shown in FIG. 9, the wireless communications device 900 includes a transceiver 904 and a data processor 906. The data processor 906 may include a memory to store data and program codes. The transceiver 904 includes a transmitter 908 and a receiver 910 that support bi-directional communications. In general, the wireless communications device 900 may include any number of transmitters 908 and/or receivers 910 for any number of communication systems and frequency bands. All or a portion of the transceiver 904 may be implemented on one or more analog ICs, RF ICs (RFICs), mixed-signal ICs, etc.

The transmitter 908 or the receiver 910 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 910. In the direct-conversion architecture, a signal is frequency-converted between RF and baseband in one stage. The super-heterodyne and direct-conversion architectures may use different circuit blocks and/or have different requirements. In the wireless communications device 900 in FIG. 9, the transmitter 908 and the receiver 910 are implemented with the direct-conversion architecture.

In the transmit path, the data processor 906 processes data to be transmitted and provides I and Q analog output signals to the transmitter 908. In the exemplary wireless communications device 900, the data processor 906 includes digital-to-analog converters (DACs) 912(1), 912(2) for converting digital signals generated by the data processor 906 into the I and Q analog output signals, e.g., I and Q output currents, for further processing.

Within the transmitter 908, lowpass filters 914(1), 914(2) filter the I and Q analog output signals, respectively, to remove undesired signals caused by the prior digital-to-analog conversion. Amplifiers (AMP) 916(1), 916(2) amplify the signals from the lowpass filters 914(1), 914(2), respectively, and provide I and Q baseband signals. An upconverter 918 upconverts the I and Q baseband signals with I and Q transmit (TX) local oscillator (LO) signals through mixers 920(1), 920(2) from a TX LO signal generator 922 to provide an upconverted signal 924. A filter 926 filters the upconverted signal 924 to remove undesired signals caused by the frequency upconversion as well as noise in a receive frequency band. A power amplifier (PA) 928 amplifies the upconverted signal 924 from the filter 926 to obtain the desired output power level and provides a transmit RF signal. The transmit RF signal is routed through a duplexer or switch 930 and transmitted via an antenna 932.

In the receive path, the antenna 932 receives signals transmitted by base stations and provides a received RF signal, which is routed through the duplexer or switch 930 and provided to a low noise amplifier (LNA) 934. The duplexer or switch 930 is designed to operate with a specific receive (RX)-to-TX duplexer frequency separation, such that RX signals are isolated from TX signals. The received RF signal is amplified by the LNA 934 and filtered by a filter 936 to obtain a desired RF input signal. Downconversion mixers 938(1), 938(2) mix the output of the filter 936 with I and Q RX LO signals (i.e., LO_I and LO_Q) from an RX LO signal generator 940 to generate I and Q baseband signals. The I and Q baseband signals are amplified by amplifiers (AMP) 942(1), 942(2) and further filtered by lowpass filters 944(1), 944(2) to obtain I and Q analog input signals, which are provided to the data processor 906. In this example, the data processor 906 includes ADCs 946(1), 946(2) for converting the analog input signals into digital signals to be further processed by the data processor 906.

In the wireless communications device 900 of FIG. 9, the TX LO signal generator 922 generates the I and Q TX LO signals used for frequency upconversion, while the RX LO signal generator 940 generates the I and Q RX LO signals used for frequency downconversion. Each LO signal is a periodic signal with a particular fundamental frequency. A TX phase-locked loop (PLL) circuit 948 receives timing information from the data processor 906 and generates a control signal used to adjust the frequency and/or phase of the TX LO signals from the TX LO signal generator 922. Similarly, an RX PLL circuit 950 receives timing information from the data processor 906 and generates a control signal used to adjust the frequency and/or phase of the RX LO signals from the RX LO signal generator 940.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

What is claimed is:

1. A circuit, comprising:
an active semiconductor structure comprising a first surface;
at least one active gate each disposed adjacent to the active semiconductor structure and each comprising:
a gate dielectric structure having a first thickness above the first surface of the active semiconductor structure; and
an on-diffusion (OD) edge (ODE) dummy gate structure, comprising:
a second gate dielectric structure having a second thickness above an end of the active semiconductor structure greater than the first thickness.

2. The circuit of claim 1, further comprising a diffusion barrier disposed adjacent to the ODE dummy gate structure.

3. The circuit of claim 1, wherein:
the gate dielectric structure is disposed on the first surface of the active semiconductor structure; and
the second gate dielectric structure is disposed on the first surface above an end of the active semiconductor structure.

4. The circuit of claim 1, wherein:
the first thickness is between 0.7 nanometers (nm) and 1.5 nm; and
the second thickness is between 2.0 nm and 3.5 nm.

5. The circuit of claim 1, wherein a ratio of the second thickness to the first thickness is at least 2.0.

6. The circuit of claim 1, wherein a ratio of the second thickness to the first thickness is between 2.0 and 3.0.

7. The circuit of claim 1, further not comprising a gate cut in the ODE dummy gate structure.

8. The circuit of claim 1, wherein:
each of the at least one active gate further comprises:
a work function metal structure disposed on the gate dielectric structure; and
a metal gate disposed on the work function metal structure; and
the ODE dummy gate structure further comprises:
a second work function metal structure disposed on the second gate dielectric structure; and
a second metal gate disposed on the second work function metal structure.

9. The circuit of claim 1, further comprising:
a second active semiconductor structure comprising a second surface;
at least one second active gate each disposed adjacent to the second active semiconductor structure and each comprising:
a third gate dielectric structure having a third thickness above the second surface of the second active semiconductor structure; and
a second ODE dummy gate structure, comprising:
a fourth gate dielectric structure having a fourth thickness above an end of the active semiconductor structure greater than the third thickness.

10. The circuit of claim 1, wherein the active semiconductor structure comprises an N-type active semiconductor structure.

11. The circuit of claim 1, wherein the active semiconductor structure comprises a P-type active semiconductor structure.

12. The circuit of claim 9, wherein the active semiconductor structure comprises a P-type active semiconductor structure, and the active second semiconductor channel structure comprises a P-type active semiconductor structure.

13. The circuit of claim 1, wherein:
the active semiconductor structure has a longitudinal axis in a first direction;
the at least one active gate has a longitudinal axis in a second direction substantially orthogonal to the first direction; and
the ODE dummy gate structure has a longitudinal axis in the second direction substantially orthogonal to the first direction.

14. The circuit of claim 1, further comprising an interlayer dielectric disposed above the active semiconductor structure, the at least one active gate, and the ODE dummy gate structure.

15. The circuit of claim 1, further comprising:
a source in the active semiconductor structure and disposed on a first side of an active gate active among the at least one active gate; and
a drain in the active semiconductor structure and disposed on a second side of the active gate opposite the first side of the active gate.

16. The circuit of claim 15, further comprising a Fin Field-Effect Transistor (FET) (FinFET) comprising the active semiconductor structure comprising at least one fin structure, the source, the drain, and the at least one active gate disposed above the at least one fin structure adjacent to the source and the drain.

17. The circuit of claim 15, further comprising a gate-all-around (GAA) Field-Effect Transistor (FET) (GAA FET) comprising the active semiconductor structure comprising at least one nanostructure, the source, the drain, and the at least one active gate disposed around the at least one nanostructure adjacent to the source and the drain.

18. The circuit of claim 1 integrated into an integrated circuit (IC).

19. The circuit of claim 1 integrated into a device selected from the group consisting of: a set top box; an entertainment unit; a navigation device; a communications device; a fixed location data unit; a mobile location data unit, a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA): a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

20. A method of fabricating a cell circuit, comprising:
forming an active semiconductor region in a substrate;
forming an active semiconductor structure comprising a first surface above the substrate in the active semiconductor region;
forming a plurality of dummy gates above the active semiconductor structure, the plurality of dummy gates comprising at least one active gate region and an on-diffusion (OD) edge (ODE) dummy gate structure region disposed above an end of the active semiconductor structure; and
replacing the plurality of dummy gates with a respective plurality of metal gates, comprising:
disposing a gate dielectric structure in the at least one active gate region and the ODE dummy gate structure region on the first surface of the active semiconductor structure, the gate dielectric structure having a first thickness above the first surface of the active semiconductor structure; and
disposing a second gate dielectric structure in the ODE dummy gate structure region on the gate dielectric structure above the end of the active semiconductor structure such that the gate dielectric structure and the second gate dielectric structure form an ODE dummy gate dielectric structure having a second thickness greater than the first thickness.

21. The method of claim 20, further comprising:
disposing a work function metal structure in the at least one active gate region on the gate dielectric structure and a second work function metal structure in the ODE dummy gate structure region on the ODE dummy gate dielectric structure; and
disposing a metal gate in the at least one active gate region on the gate dielectric structure on the work function metal structure, and a second metal gate in the ODE dummy gate structure region on the ODE dummy gate dielectric structure on the work function metal structure.

22. The method of claim 20, further comprising not cutting the plurality of metal gates.

23. The method of claim 20, further comprising an interlayer dielectric material above the active semiconductor structure and the plurality of metal gates to form an interlayer dielectric.

24. The method of claim 20, further comprising:
forming a source on a first end portion of the active semiconductor structure; and
forming a drain on a second end portion of the active semiconductor structure opposite of the first end portion.

25. The method of claim 20, wherein:
the first thickness is between 0.7 nanometers (nm) and 1.5 nm; and
the second thickness is between 2.0 nm and 3.5 nm.

26. The method of claim 20, wherein a ratio of the second thickness to the first thickness is at least 2.0.

27. The method of claim 20, wherein a ratio of the second thickness to the first thickness is between 2.0 and 3.0.
